(19) United States
(12) Patent Application Publication
(10) Pub. No.: US 2022/0317490 A1
(43) Pub. Date: Oct. 6, 2022

(54) ARRAY SUBSTRATE, MANUFACTURING METHOD THEREOF, AND LIQUID CRYSTAL DISPLAY PANEL

(71) Applicant: TCL China Star Optoelectronics Technology Co., Ltd., Shenzhen (CN)

(72) Inventor: Haijun Wang, Shenzhen (CN)

(73) Assignee: TCL China Star Optoelectronics Technology Co., Ltd., Shenzhen (CN)

(21) Appl. No.: 16/972,113

(22) PCT Filed: Nov. 19, 2020
(86) PCT No.: PCT/CN2020/130121

§ 371 Date: Dec. 4, 2020

(30) Foreign Application Priority Data
Sep. 3, 2020 (CN) 202010914765.1

(51) Int. Cl. G02F 1/1368; G02F 1/1362

(52) U.S. Cl. CPC G02F 1/1368; G02F 1/136209; G02F 1/136222; G02F 1/136213; G02F 1/136286

(57) ABSTRACT

The present application provides an array substrate, a manufacturing method thereof, and a liquid crystal display panel. The array substrate includes: a substrate; display thin-film transistors arranged in an array on the substrate; and photosensitive thin-film transistors arranged on the substrate, wherein the display thin-film transistors and the photosensitive thin-film transistors are arranged at intervals in the same layer.

### BACKGROUND OF INVENTION

### Field of Invention

The present application relates to a field of display technology, and in particular to an array substrate, a manufacturing method thereof, and a liquid crystal display panel.

### Description of Prior Art

Thin-film transistor liquid crystal displays (TFT-LCDs) are widely used in the flat panel display industry due to their features of lightness, thinness, and small sizes, as well as low power consumption, radiation-free, and relatively low manufacturing cost. In order to broaden the commercial and household functions of LCD displays, many functions are now integrated into the displays, such as color temperature sensing, laser sensing, gas sensing, etc., to improve the present application scenarios of LCD displays. However, many integrated functions are still in a new and initial development stage, and there are still many processes and related designs that need to be improved in order to improve the performance of liquid crystal displays with multiple integrated functions.

In order to realize the laser sensing function of liquid crystal displays, many panel manufacturers prepare s sensor with a laser sensing function separately on a glass, and then attach it to an open cell (liquid crystal panel) with a display function to achieve the liquid crystal display having a laser sensing effect. However, although this method can achieve the functions of integrated laser sensing and display, it requires a relatively complicated manufacturing process and a high cost (requiring more glass and process), and the entire display panel has a relatively high overall thickness (higher glass thickness), thus unable to achieve large-scale commercial applications.

### SUMMARY OF INVENTION

The present application provides an array substrate, a manufacturing method thereof, and a liquid crystal display panel, which are used to prepare photosensitive thin-film transistors and display thin-film transistors on a same substrate, thereby saving manufacturing processes and reducing product costs.

In order to solve the above problems, the technical solutions provided by the present application are as follows:

An array substrate, including:

a substrate;

display thin-film transistors disposed in an array on the substrate; and

photosensitive thin-film transistors disposed on the substrate,

wherein the display thin-film transistors and the photosensitive thin-film transistors are arranged at intervals in a same layer.

In the array substrate according to the present application, the array substrate further includes:

a first metal layer disposed on the substrate, wherein the first metal layer includes a first electrode, a second electrode, and a third electrode arranged at intervals;

a first insulating layer disposed above the first metal layer;

a semiconductor layer disposed above the first insulating layer, wherein the semiconductor layer includes a first semiconductor layer and a second semiconductor layer, the first semiconductor layer is disposed above the first electrode, and the second semiconductor layer is disposed above the second electrode;

a second metal layer disposed above the semiconductor layer and the first insulating layer, wherein the second metal layer includes a fourth electrode, a fifth electrode, a source, a drain, and a sixth electrode, wherein the fourth electrode and the fifth electrode are disposed above the first semiconductor layer; the source and the drain are disposed above the second semiconductor layer; and the sixth electrode is disposed above the third electrode;

a second insulating layer disposed above the second metal layer; and

a transparent electrode disposed above the second insulating layer and connected to the sixth electrode and the drain.

In the array substrate according to the present application, the second insulating layer is provided with openings corresponding to the drain and the sixth electrode; and the transparent electrode is connected to the sixth electrode and the drain through the openings in the second insulating layer.

In the array substrate according to the present application, the array substrate further includes a storage capacitor disposed on the substrate, wherein the storage capacitor includes the third electrode and the sixth electrode arranged oppositely, and the sixth electrode is connected to a drain of the display thin-film transistors through the transparent electrode.

In the array substrate according to the present application, the display thin-film transistors are disposed between the storage capacitor and the photosensitive thin-film transistors.

In the array substrate according to the present application, each of the display thin-film transistors includes the second electrode, the second semiconductor layer, the source, and the drain that are stacked on the substrate;

each of the photosensitive thin-film transistors includes the first electrode, the first semiconductor layer, the fourth electrode, and the fifth electrode that are stacked on the substrate; and

each of the first semiconductor layer and the second semiconductor layer includes an amorphous silicon layer and an N-type heavily doped amorphous silicon layer that are stacked, and the N-type heavily doped amorphous silicon layer covers two opposite edge regions of the amorphous silicon layer and exposes the amorphous silicon layer in a channel region of the first semiconductor layer and/or the second semiconductor layer.

In the array substrate according to the present application, the array substrate further includes a light-shielding layer on the display thin-film transistors and the photosensitive thin-film transistors; the light-shielding layer includes a light-transmitting area corresponding to each of the photosensitive thin-film transistors and an opening area corresponding to a display area.

In the array substrate according to the present application, the light-transmitting area of the light-shielding layer is provided with an openings corresponding to the first semiconductor layer, and the openings corresponds to the channel region.

In the array substrate according to the present application, in each of the photosensitive thin-film transistors, the fourth electrode is connected to a power line, and the fifth electrode is connected to a signal reading wiring.

The present application also provides a method of manufacturing an array substrate, including:
Step S10: sequentially forming a thin-film transistor layer and a transparent electrode on a substrate, wherein the thin-film transistor layer including display thin-film transistors and photosensitive thin-film transistors, and the transparent electrode is electrically connected to each of the display thin-film transistors;
Step S20: forming a layer of a light-shielding material above each of the display thin-film transistors and each of the photosensitive thin-film transistors, and patterning the light-shielding material to form a light-shielding layer; and
Step S30: patterning the light-shielding layer by exposing the light-shielding layer with a mask, and developing the exposed light-shielding layer, to form a light-transmitting area corresponding to each of the photosensitive thin-film transistors, a first spacer and a second spacer corresponding to each of the display thin-film transistors, and an opening area corresponding to a display area.

In the method of manufacturing the array substrate according to the present application, in the step S30, the light-shielding layer is exposed by using the mask with various transmittances, and the mask includes a first transmittance area, a second transmittance area, a third transmittance area, and a fourth transmittance area; and

wherein the second transmittance area is disposed corresponding to the opening area of the light-transmitting area and the display area, the third transmittance area is disposed corresponding to the first spacer, the fourth transmittance area is disposed corresponding to the second spacer, and the first transmittance area is disposed corresponding to an area other than the display area, the first spacer, and the second spacer.

The present application also provides a liquid crystal display panel, including an array substrate, a color filter substrate, and a liquid crystal layer disposed between the array substrate and the color filter substrate; the array substrate includes:

a substrate;

display thin-film transistors disposed in an array on the substrate; and

photosensitive thin-film transistors disposed on the substrate,

wherein the display thin-film transistors and the photosensitive thin-film transistors are arranged at intervals in a same layer.

In the liquid crystal display panel according to the present application, the array substrate further includes:

a first metal layer disposed on the substrate, wherein the first metal layer includes a first electrode, a second electrode, and a third electrode arranged at intervals;

a first insulating layer disposed above the first metal layer;

a semiconductor layer disposed above the first insulating layer, wherein the semiconductor layer includes a first semiconductor layer and a second semiconductor layer, the first semiconductor layer is disposed above the first electrode, and the second semiconductor layer is disposed above the second electrode;

a second metal layer disposed above the semiconductor layer and the first insulating layer, wherein the second metal layer includes a fourth electrode, a fifth electrode, a source, a drain, and a sixth electrode, wherein the fourth electrode and the fifth electrode are disposed above the first semiconductor layer; the source and the drain are disposed above the second semiconductor layer; and the sixth electrode is disposed above the third electrode;

a second insulating layer disposed above the second metal layer; and

a transparent electrode disposed above the second insulating layer and connected to the sixth electrode and the drain.

In the liquid crystal display panel according to the present application, the second insulating layer is provided with openings corresponding to the drain and the sixth electrode; and the transparent electrode is connected to the sixth electrode and the drain through the openings in the second insulating layer.

In the liquid crystal display panel according to the present application, the array substrate further includes a storage capacitor disposed on the substrate, the storage capacitor includes the third electrode and the sixth electrode arranged oppositely, and the sixth electrode is connected to a drain of the display thin-film transistors through the transparent electrode.

In the liquid crystal display panel according to the present application, the display thin-film transistors are disposed between the storage capacitor and the photosensitive thin-film transistors.

In the liquid crystal display panel according to the present application, each of the display thin-film transistors includes the second electrode, the second semiconductor layer, the source, and the drain that are stacked on the substrate;

each of the photosensitive thin-film transistors includes the first electrode, the first semiconductor layer, the fourth electrode, and the fifth electrode that are stacked on the substrate; and

each of the first semiconductor layer and the second semiconductor layer include an amorphous silicon layer and an N-type heavily doped amorphous silicon layer that are stacked, and the N-type heavily doped amorphous silicon layer covers two opposite edge regions of the amorphous silicon layer and exposes the amorphous silicon layer in a channel region of the first semiconductor layer and/or the second semiconductor layer.

In the liquid crystal display panel according to the present application, the array substrate further includes a light-shielding layer on the display thin-film transistors and the photosensitive thin-film transistors; the light-shielding layer includes a light-transmitting area corresponding to each of the photosensitive thin-film transistors and an opening area corresponding to a display area.

In the liquid crystal display panel according to the present application, the light-transmitting area of the light-shielding layer is provided with an openings corresponding to the first semiconductor layer, and the openings corresponds to the channel region.

In the liquid crystal display panel according to the present application, in each of the photosensitive thin-film transistors, the fourth electrode is connected to a power line, and the fifth electrode is connected to a signal reading wiring.

In the present application, the photosensitive thin-film transistors and the display thin-film transistors are prepared on the same substrate to realize the functions of integrated sensing and display, while reducing the thickness of the array substrate; and one process is used to prepare the light-transmitting area and the light-shielding area of the light-shielding layer, thereby saving process technology and reducing product cost.

### BRIEF DESCRIPTION OF DRAWINGS

FIG. 1 is a schematic structural diagram of an array substrate provided by an embodiment of the present application.

FIG. 2 is a flow chart of steps of the method of manufacturing an array substrate provided by an embodiment of the present application.

FIG. 3A to FIG. 3C are schematic structural diagrams of an array substrate in the manufacturing process provided by an embodiment of the present application.

FIG. 4 is a schematic structural diagram of a liquid crystal display panel provided by an embodiment of the present application.

### DETAILED DESCRIPTION OF PREFERRED EMBODIMENTS

The present application provides an array substrate, a manufacturing method thereof, and a liquid crystal display panel. In order to make the purpose, technical solution, and effect of the present application clearer and more definite, the present application is further described in detail below with reference to the accompanying drawings and examples. It should be understood that the specific embodiments described herein are only used to explain the present application and are not used to limit the present application.

### Embodiment 1

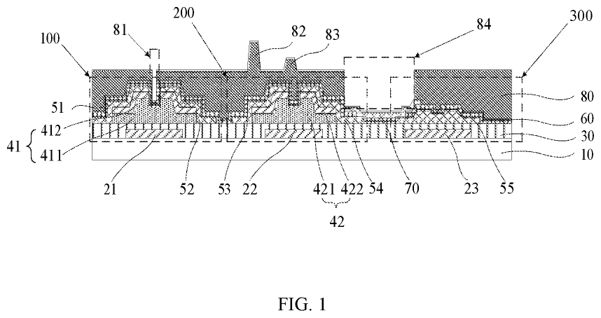

Referring to FIG. 1, which is a schematic structural diagram of an array substrate provided by an embodiment of the present application.

In this embodiment, the array substrate includes a substrate 10; display thin-film transistors 200 disposed in an array on the substrate 10; photosensitive thin-film transistors 100 disposed on the substrate 10, wherein the display thin-film transistors 200 and the photosensitive thin-film transistors 100 are arranged at intervals in a same layer.

The array substrate further includes a first metal layer, a first insulating layer 30, a semiconductor layer, a second metal layer, a second insulating layer 60, and a transparent electrode 70 stacked on the substrate 10 in sequence.

In this embodiment, the substrate 10 is a PI substrate, mainly made of polyimide, and the PI material can effectively improve the light-transmittance.

In this embodiment, the first metal layer includes a first electrode 21, a second electrode 22, and a third electrode 23 arranged at intervals; material of the first metal layer may include, but is not particularly limited to, copper, aluminum, silver, and so on.

In this embodiment, the semiconductor layer is disposed above the first insulating layer 30, and the semiconductor layer includes a first semiconductor layer 41 and a second semiconductor layer 42. The first semiconductor layer 41 is disposed above the first electrode 21; and the second semiconductor layer 42 is disposed above the second electrode 22, wherein the first semiconductor layer 41 includes an amorphous silicon layer 411 and an N-type heavily doped amorphous silicon layer 412 that are stacked, and the N-type heavily doped amorphous silicon layer 412 covers two opposite edge regions of the amorphous silicon layer 411 and exposes the amorphous silicon layer 411 in a channel region of the first semiconductor layer 41. The second semiconductor layer 42 includes an amorphous silicon layer 421 and an N-type heavily doped amorphous silicon layer 422 that are stacked, and the N-type heavily doped amorphous silicon layer 442 covers two opposite edge regions of the amorphous silicon layer 421 and exposes the amorphous silicon layer 411 in a channel region of the second semiconductor layer 42.

In this embodiment, the second metal layer is disposed above the semiconductor layer and the first insulating layer 30; the second metal layer includes a fourth electrode 51, a fifth electrode 52, a source 53, a drain 54, and a sixth electrode 55.

The fourth electrode 51 and the fifth electrode 52 are located above the first semiconductor layer 41 and cover two opposite edge regions of the first semiconductor layer 41. The source 53 and the drain 54 are located above the second semiconductor layer 42 and cover two opposite edge regions of the second semiconductor layer 42. The sixth electrode 55 is located above the third electrode 23.

In this embodiment, the second insulating layer 60 is formed with openings corresponding to the drain 54 and the sixth electrode 55; the transparent electrode 70 is disposed above the second insulating layer 60, and the transparent electrode 70 is connected to the sixth electrode 55 and the drain 54 through the openings on the second insulating layer 60.

In this embodiment, each of the photosensitive thin-film transistors 100 includes the first electrode 21, the first semiconductor layer 41, the fourth electrode 51, and the fifth electrode 52 that are stacked on the substrate 10. Each of the display thin-film transistors 200 includes the second electrode 22, the second semiconductor layer 42, the source 53, and the drain 54 that are stacked on the substrate 10. The display thin-film transistors 200 and the photosensitive thin-film transistors 100 are arranged at intervals in a same layer.

In each of the photosensitive thin-film transistors 100, the fourth electrode 51 is connected to a power line, and the fifth electrode 52 is connected to a signal reading wiring.

In this embodiment, the photosensitive thin-film transistors 100 and the display thin-film transistors 200 are prepared on the same substrate 10 to realize the functions of integrated sensing and display, while reducing the thickness of the array substrate.

In this embodiment, the array substrate further includes a storage capacitor 300 on the substrate 10; the display thin-film transistors 200 are located between the storage capacitor 300 and the photosensitive thin-film transistors 100.

The storage capacitor 300 includes the third electrode 23 and the sixth electrode 55 oppositely arranged, and two opposite pole plates of the storage capacitor 300 are the third electrode 23 and the sixth electrode 55. The sixth electrode 55 is connected to the drain 54 of the display thin-film transistors 200 through the transparent electrode 70.

In this embodiment, the array substrate further includes a light-shielding layer 80 located on the display thin-film transistors 200 and the photosensitive thin-film transistors 100; and material of the light-shielding layer 80 may include, but is not particularly limited to black light-shielding glue.

The light-shielding layer 80 includes a light-transmitting area 81 corresponding to the photosensitive thin-film transistors 100, a first spacer 82 and a second spacer 83 corresponding to the display thin-film transistors 200, and an opening area 84 corresponding to the display area. The light-transmitting area 81, the first spacer 82, the second spacer 83, and the opening area 84 are prepared through the same photomask process.

In this embodiment, the light-transmitting area 81 of the light-shielding layer 80 is formed with an opening corresponding to the first semiconductor layer 41; wherein, the opening corresponds to the channel region of the first semiconductor layer 41.

### Embodiment 2

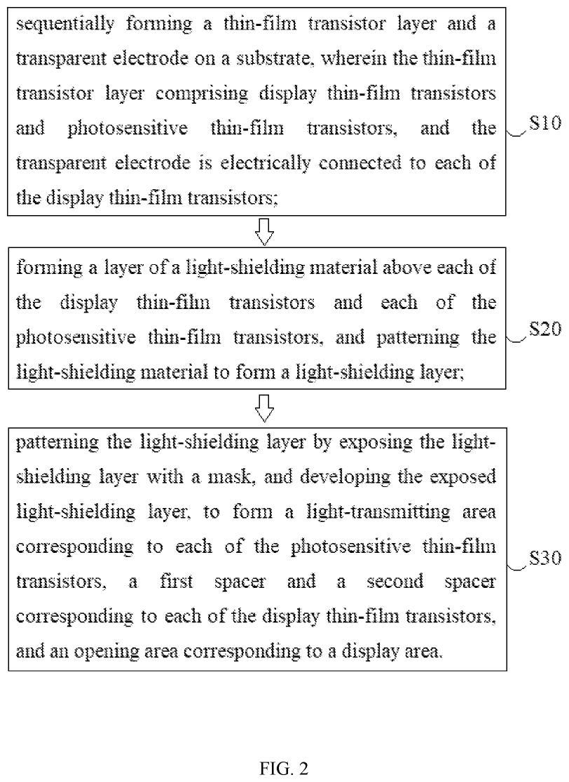

Referring to FIG. 2, which is a flowchart of steps of a method of manufacturing an array substrate provided by an embodiment of the present application.

In this embodiment, the manufacturing method of the array substrate includes:

Step S10: sequentially forming a thin-film transistor layer and a transparent electrode 70 on a substrate, wherein the thin-film transistor layer including display thin-film transistors 200 and photosensitive thin-film transistors 100, and the transparent electrode 70 is electrically connected to each of the display thin-film transistors 100.

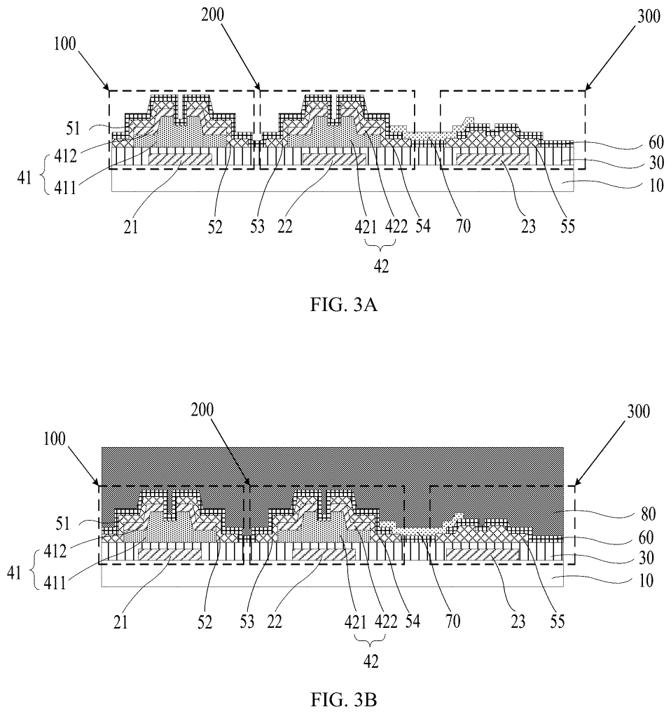

The step S10 further includes preparing a storage capacitor 300 on the substrate 10, wherein the photosensitive thin-film transistors 100, the display thin-film transistors 200, and the storage capacitor 300 are arranged at intervals in the same layer, as shown in FIG. 3A.

In the step S10, it further includes:

Step S11: forming a first metal layer on the substrate 10, wherein the first metal layer includes a first electrode 21, a second electrode 22, and a third electrode 23 arranged at intervals.

Step S12: forming a first insulating layer 30 and a semiconductor layer on the first metal layer, wherein the semiconductor layer includes a first semiconductor layer 41 and a second semiconductor layer 42; the first semiconductor layer 41 is disposed above the first electrode 21; and the second semiconductor layer 42 is disposed above the second electrode 22, wherein the first semiconductor layer 41 includes an amorphous silicon layer 411 and an N-type heavily doped amorphous silicon layer 412 that are stacked, and the second semiconductor layer 42 includes an amorphous silicon layer 421 and an N-type heavily doped amorphous silicon layer 422 that are stacked.

Step S13: forming a second metal layer on the semiconductor layer, wherein the second metal layer includes a fourth electrode 51, a fifth electrode 52, a source 53, a drain 54, and a sixth electrode 55; the fourth electrode 51 and the fifth electrode 52 are located above the first semiconductor layer 41 and cover two opposite edge regions of the first semiconductor layer 41; the source 53 and the drain 54 are located above the second semiconductor layer 42 and cover two opposite edge regions of the second semiconductor layer 42; and the sixth electrode 55 is located above the third electrode 23.

Step S14: forming a second insulating layer 60 and a transparent electrode 70 on the second metal layer.

In the step S10, each of the photosensitive thin-film transistors 100 includes the first electrode 21, the first semiconductor layer 41, the fourth electrode 51, and the fifth electrode 52 that are stacked on the substrate 10; each of the display thin-film transistors 200 includes the second electrode 22, the second semiconductor layer 42, the source 53, and the drain 54 that are stacked on the substrate 10; and the storage capacitor 300 includes the third electrode 23 and the sixth electrode 55 disposed opposite to each other.

Step S20: forming a layer of a light-shielding material above each of the display thin-film transistors 200 and each of the photosensitive thin-film transistors 100 and patterning the light-shielding material to form a light-shielding layer 80, as shown in FIG. 3B.

Material of the light-shielding layer 80 may include but is not particularly limited to black light-shielding glue.

Step S30: patterning the light-shielding layer 80 by exposing the light-shielding layer 80 with a mask, and developing the exposed light-shielding layer 80, to form a light-transmitting area 81 corresponding to each of the photosensitive thin-film transistors 100, a first spacer 82 and a second spacer 83 corresponding to each of the display thin-film transistors 200, and an opening area 84 corresponding to a display area, as shown in FIG. 3C.

In step S30, the light-shielding layer 80 is exposed by using the mask with various transmittances, and the mask includes a first transmittance area Tr1, a second transmittance area Tr2 a third transmittance area Tr3 and a fourth transmittance area Tr4 wherein the second transmittance area Tr2 is disposed corresponding to the opening area 84 of the light-transmitting area 81 and the display area, the third transmittance area Tr3 is disposed corresponding to the first spacer 82, the fourth transmittance area Tr4 is disposed corresponding to the second spacer 83, and the first transmittance area Tr1 is disposed corresponding to the remaining area.

In this embodiment, the second transmittance area Tr2 is smaller than the first transmittance area Tr1, the first transmittance area Tr1 is smaller than the fourth transmittance area Tr4; and the fourth transmittance area Tr4 is smaller than the third transmittance area Tr3, wherein the second transmittance area Tr2 is opaque, the third transmittance area Tr3 is fully transparent, that is, having light-transmittance of 100%, and each of the first transmittance area Tr1 and the fourth transmittance area Tr4 has light-transmittance ranging from 0 to 100%, which are not particularly limited thereto.

In this embodiment, the light-transmitting area 81 of the light-shielding layer 80, the first spacer 82, the second spacer 83, and the opening area 84 corresponding to the display area are prepared by using one photomask process, thereby saving manufacturing processes and reducing product costs.

### Embodiment 3

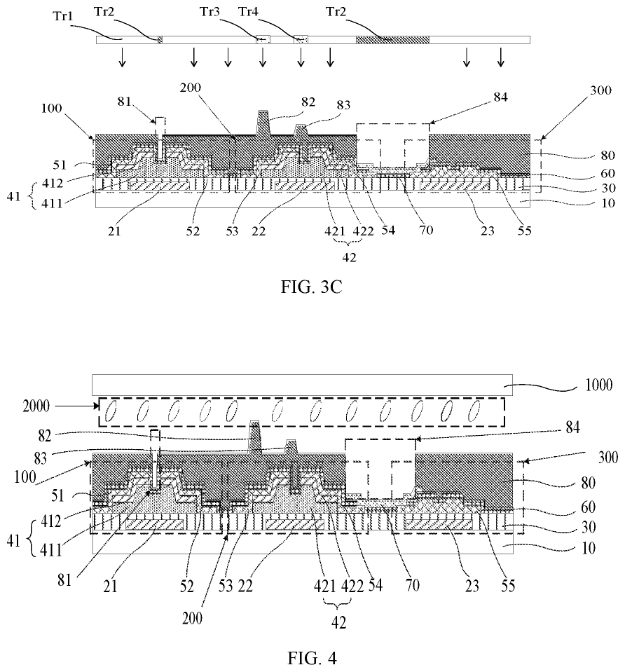

Referring to FIG. 4, which is a schematic structural diagram of a liquid crystal display panel provided by an embodiment of the present application.

In this embodiment, the liquid crystal display panel includes the array substrate described in Embodiment 1, the color filter substrate 1000, and a liquid crystal layer 2000 located between the array substrate and the color filter substrate 1000.

In this embodiment, details of the array substrate has been described in Embodiment 1 and will not be repeated herein for brevity.

In summary, the present application provides an array substrate, a manufacturing method thereof, and a liquid crystal display panel. The array substrate includes: a substrate; display thin-film transistors arranged in an array on the substrate; and photosensitive thin-film transistors arranged on the substrate, wherein the display thin-film transistors and the photosensitive thin-film transistors are arranged at intervals in the same layer.

In the present application, the photosensitive thin-film transistors and the display thin-film transistors are prepared on the same substrate to realize the functions of integrated sensing and display, while reducing the thickness of the array substrate; and one process is used to prepare the light-transmitting area and the light-shielding area of the light-shielding layer, thereby saving process technology and reducing product cost.

It can be understood that for those of ordinary skill in the art, equivalent substitutions or changes can be made according to the technical solutions and inventive concepts of the present application, and all these changes or substitutions shall fall within the protection scope of the appended claims of the present application.

What is claimed is:

1. An array substrate, comprising:
a substrate;
display thin-film transistors disposed in an array on the substrate; and
photosensitive thin-film transistors disposed on the substrate,
wherein the display thin-film transistors and the photosensitive thin-film transistors are arranged at intervals in a same layer.

2. The array substrate according to claim 1, further comprising:
a first metal layer disposed on the substrate, wherein the first metal layer comprises a first electrode, a second electrode, and a third electrode arranged at intervals;
a first insulating layer disposed above the first metal layer;
a semiconductor layer disposed above the first insulating layer, wherein the semiconductor layer comprises a first semiconductor layer and a second semiconductor layer, the first semiconductor layer is disposed above the first electrode, and the second semiconductor layer is disposed above the second electrode;
a second metal layer disposed above the semiconductor layer and the first insulating layer, wherein the second metal layer comprises a fourth electrode, a fifth electrode, a source, a drain, and a sixth electrode, wherein the fourth electrode and the fifth electrode are disposed above the first semiconductor layer; the source and the drain are disposed above the second semiconductor layer; and the sixth electrode is disposed above the third electrode;
a second insulating layer disposed above the second metal layer; and
a transparent electrode disposed above the second insulating layer and connected to the sixth electrode and the drain.

3. The array substrate according to claim 2, wherein the second insulating layer is provided with openings corresponding to the drain and the sixth electrode; and the transparent electrode is connected to the sixth electrode and the drain through the openings in the second insulating layer.

4. The array substrate according to claim 2, further comprising a storage capacitor disposed on the substrate, wherein the storage capacitor comprises the third electrode and the sixth electrode arranged oppositely, and the sixth electrode is connected to a drain of the display thin-film transistors through the transparent electrode.

5. The array substrate according to claim 4, wherein the display thin-film transistors are disposed between the storage capacitor and the photosensitive thin-film transistors.

6. The array substrate according to claim 2, wherein each of the display thin-film transistors comprises the second electrode, the second semiconductor layer, the source, and the drain that are stacked on the substrate;
each of the photosensitive thin-film transistors comprises the first electrode, the first semiconductor layer, the fourth electrode, and the fifth electrode that are stacked on the substrate; and
each of the first semiconductor layer and the second semiconductor layer comprises an amorphous silicon layer and an N-type heavily doped amorphous silicon layer that are stacked, and the N-type heavily doped amorphous silicon layer covers two opposite edge regions of the amorphous silicon layer and exposes the amorphous silicon layer in a channel region of the first semiconductor layer and/or the second semiconductor layer.

7. The array substrate according to claim 6, further comprising a light-shielding layer on the display thin-film transistors and the photosensitive thin-film transistors; the light-shielding layer comprises a light-transmitting area corresponding to each of the photosensitive thin-film transistors and an opening area corresponding to a display area.

8. The array substrate according to claim 7, wherein the light-transmitting area of the light-shielding layer is provided with an opening corresponding to the first semiconductor layer, and the opening corresponds to the channel region.

9. The array substrate according to claim 6, wherein, in each of the photosensitive thin-film transistors, the fourth electrode is connected to a power line, and the fifth electrode is connected to a signal reading wiring.

10. A method of manufacturing an array substrate, comprising:
Step S10: sequentially forming a thin-film transistor layer and a transparent electrode on a substrate, wherein the thin-film transistor layer comprising display thin-film transistors and photosensitive thin-film transistors, and the transparent electrode is electrically connected to each of the display thin-film transistors;
Step S20: forming a layer of a light-shielding material above each of the display thin-film transistors and each of the photosensitive thin-film transistors, and patterning the light-shielding material to form a light-shielding layer; and
Step S30: patterning the light-shielding layer by exposing the light-shielding layer with a mask, and developing the exposed light-shielding layer, to form a light-transmitting area corresponding to each of the photosensitive thin-film transistors, a first spacer and a second spacer corresponding to each of the display thin-film transistors, and an opening area corresponding to a display area.

11. The method of manufacturing the array substrate according to claim 10, wherein in the step S30, the light-shielding layer is exposed by using the mask with various transmittances, and the mask comprises a first transmittance area, a second transmittance area, a third transmittance area, and a fourth transmittance area; and
wherein the second transmittance area is disposed corresponding to the opening area of the light-transmitting area and the display area, the third transmittance area is disposed corresponding to the first spacer, the fourth transmittance area is disposed corresponding to the second spacer, and the first transmittance area is disposed corresponding to an area other than the display area, the first spacer, and the second spacer.

12. A liquid crystal display panel, comprising an array substrate, a color filter substrate, and a liquid crystal layer disposed between the array substrate and the color filter substrate; the array substrate comprises:
a substrate;
display thin-film transistors disposed in an array on the substrate; and
photosensitive thin-film transistors disposed on the substrate,
wherein the display thin-film transistors and the photosensitive thin-film transistors are arranged at intervals in a same layer.

13. The liquid crystal display panel according to claim 12, wherein the array substrate further comprises:
a first metal layer disposed on the substrate, wherein the first metal layer comprises a first electrode, a second electrode, and a third electrode arranged at intervals;
a first insulating layer disposed above the first metal layer;
a semiconductor layer disposed above the first insulating layer, wherein the semiconductor layer comprises a first semiconductor layer and a second semiconductor layer, the first semiconductor layer is disposed above the first electrode, and the second semiconductor layer is disposed above the second electrode;
a second metal layer disposed above the semiconductor layer and the first insulating layer, wherein the second metal layer comprises a fourth electrode, a fifth electrode, a source, a drain, and a sixth electrode, wherein the fourth electrode and the fifth electrode are disposed above the first semiconductor layer; the source and the drain are disposed above the second semiconductor layer; and the sixth electrode is disposed above the third electrode;
a second insulating layer disposed above the second metal layer; and
a transparent electrode disposed above the second insulating layer and connected to the sixth electrode and the drain.

14. The liquid crystal display panel according to claim 13, wherein the second insulating layer is provided with openings corresponding to the drain and the sixth electrode; and the transparent electrode is connected to the sixth electrode and the drain through the openings in the second insulating layer.

15. The liquid crystal display panel according to claim 13, wherein the array substrate further comprises a storage capacitor disposed on the substrate, the storage capacitor comprises the third electrode and the sixth electrode arranged oppositely, and the sixth electrode is connected to a drain of the display thin-film transistors through the transparent electrode.

16. The liquid crystal display panel according to claim 15, wherein the display thin-film transistors are disposed between the storage capacitor and the photosensitive thin-film transistors.

17. The liquid crystal display panel according to claim 13, wherein each of the display thin-film transistors comprises the second electrode, the second semiconductor layer, the source, and the drain that are stacked on the substrate;
each of the photosensitive thin-film transistors comprises the first electrode, the first semiconductor layer, the fourth electrode, and the fifth electrode that are stacked on the substrate; and
each of the first semiconductor layer and the second semiconductor layer comprise an amorphous silicon layer and an N-type heavily doped amorphous silicon layer that are stacked, and the N-type heavily doped amorphous silicon layer covers two opposite edge regions of the amorphous silicon layer and exposes the amorphous silicon layer in a channel region of the first semiconductor layer and/or the second semiconductor layer.

18. The liquid crystal display panel according to claim 17, wherein the array substrate further comprises a light-shielding layer on the display thin-film transistors and the photosensitive thin-film transistors; the light-shielding layer comprises a light-transmitting area corresponding to each of the photosensitive thin-film transistors and an opening area corresponding to a display area.

19. The liquid crystal display panel according to claim 18, wherein the light-transmitting area of the light-shielding layer is provided with an opening corresponding to the first semiconductor layer, and the opening corresponds to the channel region.

20. The liquid crystal display panel according to claim 17, wherein, in each of the photosensitive thin-film transistors, the fourth electrode is connected to a power line, and the fifth electrode is connected to a signal reading wiring.
